(19) United States
(12) Patent Application Publication
(10) Pub. No.: US 2004/0266218 A1
(43) Pub. Date: Dec. 30, 2004

(54) Methods for forming a gap filling layer using high density plasma

(76) Inventor: Young Min Kwon, Bupyeong-gu (KR)

Correspondence Address: GROSSMAN & FLIGHT LLC, Suite 4220, 20 North Wacker Drive, Chicago, IL, 60606-6357, US

(21) Appl. No.: 10/877,726

(22) Filed: Jun. 25, 2004

(30) Foreign Application Priority Data
Jun. 25, 2003 (KR) 10-2003-0041452

(51) Int. Cl. H01L 21/4763; H01L 21/31; H01L 21/469

(52) U.S. Cl. 438/778; 438/622; 438/788

(57) ABSTRACT

Methods of forming a gap filling layer using high density plasma are disclosed. A disclosed method comprises directing at least one gas for ILD deposition and at least one gas for etching into a chamber containing a substrate having at least one predetermined structure; depositing a first ILD over the substrate until a thickness of the first ILD reaches a predetermined thickness; suspending supply of the gas for ILD deposition into the chamber; removing at least one part of the first ILD; re-starting the supply of the gas for ILD deposition into the chamber; and depositing a second ILD on the first ILD

### FIELD OF THE DISCLOSURE

The present disclosure relates generally to semiconductor device fabrication and, more particularly, to methods for forming a gap filling layer using high density plasma.

### BACKGROUND

With rapid advances in semiconductor device manufacturing technology, the high-integration of semiconductor devices is continuously progressing. Accordingly, the line width of and distance between adjacent interconnect lines in a circuit are narrowing more and more.

When multi-layer interconnect lines are formed in a memory device or a logic device, a planarization process is first performed. Then, an inter-layer dielectric (hereinafter referred to as ^{˜}ILD”) to insulate between an upper layer and a lower layer is deposited by means of a coating method such as chemical vapor deposition (hereinafter referred to as ^{˜}CVD”) or spin on glass (hereinafter referred to as ^{˜}SOG”).

When forming an ILD by using CVD, such as a boron phosphorus silicate glass (hereinafter referred as to ^{˜}BPSG”), a silicon oxide layer (SiO₂) doped with boron (B) and phosphorus (P) is deposited over and between adjacent interconnect lines by means of plasma enhanced CVD (hereinafter referred as to ^{˜}PECVD”). Then, the wafer having the silicon oxide layer is heat-treated at a temperature of more than 850° C. so that the PBSG layer reflows. As a result, the gaps between adjacent interconnect lines are filled with the ILD material without voids. However, such heating process of a wafer at a high temperature to achieve void-free gap fill may cause deterioration of the semiconductor device.

When forming an ILD by using SOG coating, liquid silicon compound is deposited over and between adjacent interconnect lines. A heat treatment process is then performed for the wafer having the silicon compound layer to change the silicon compound into silicon oxide (SiO₂). However, in order to obtain a satisfactory flatness for the ILD, an SOG etch back process must be performed after an additional CVD insulating layer is formed on the then-formed ILD. Therefore, the manufacturing process becomes complicated.

Moreover, the above-mentioned PECVD and SOG coating methods have exhibited limitations in forming a void free ILD as distances between adjacent interconnect lines become narrower and narrower.

Thus, several new ILD deposition processes have been developed to maximize gap fill capability and simplify the manufacturing process. One of these processes is high-density plasma CVD (hereinafter referred to as ^{˜}HDP CVD”). In HDP CVD, an electric field and a magnetic field capable of producing a higher ionization efficiency than that of conventional PECVD are applied to form high-density plasma ions and a source gas is decomposed to form an ILD over a wafer. Along with a source power to generate plasma, a bias power to etch the ILD deposited on the wafer is applied while the ILD is deposited. Therefore, the deposition and the sputter etching of the ILD are performed simultaneously.

If the ILD is etched while the ILD is deposited over and between adjacent interconnect lines, the gaps between adjacent interconnect lines can be readily filled without voids. The HDP CVD process is applicable to multi-layer interconnect lines. In this case, an ILD is formed by means of HDP CVD and chemical mechanical polishing (hereinafter referred to as ^{˜}CMP”) is then performed to planarize the ILD.

Besser et al., U.S. Pat. No. 6,566,252, describes a method for the simultaneous deposition and sputtering of TEOS. Besser et al. use TEOS as a high-density plasma (HDP) inter-layer dielectric (ILD). The Besser et al. process includes depositing TEOS and etching away excessive TEOS simultaneously, thereby avoiding hydrogen embrittlement of, and subsequent void formation in, aluminum lines.

Wang et al., U.S. Pat. No. 6,479,881, describes a low temperature process for forming intermetal gap-filling insulating layers in silicon wafer integrated circuitry. In Wang et al., a double dielectric layer is formed by an in situ low temperature two step deposition HDP-CVD process separated by a cool-down period.

Liu et al., U.S. Pat. No. 6,211,040, discloses a two-step, low argon, HDP CVD oxide deposition process. That process includes depositing a silicon dioxide liner layer over features and gaps, yet leaving the gaps open by means of HDP CVD; and depositing a silicon dioxide gap filling layer over the silicon dioxide liner layer to fill the gaps by means of HDP CVD.

However, although HDP CVD provides excellent gap fill capability, when the ILD is formed by means of HDP CVD, the upper parts of the gaps between adjacent interconnect lines may be clogged because the deposition speed for the top corners of the interconnect lines is relatively fast and the sputter-etched ILD material may be re-deposited on the side wall(s) of the interconnect lines.

FIGS. 1a and 1b illustrate the process of void formation in an ILD. As shown in FIG. 1a, the upper parts of the gaps 33 between adjacent interconnect lines 20 are narrower in width than the lower parts due to rapid deposition on the top corners of the interconnect lines and re-deposition of the sputter-etched ILD material. Therefore, as shown in FIG. 1b, the upper parts of the gaps 33 are clogged for further sputter etching and voids 35 are formed in the gaps 33 between adjacent interconnect lines 20 to obstruct complete gap filling.

Moreover, spacing between adjacent interconnect lines in high-integrated semiconductor devices of less than 0.13 micron design rule is so narrow that the gaps may not be completely filled with HDP oxide. If the etching rate is increased in order to fill such narrow gaps, the gap filling quality can be improved but pre-formed lower patterns may be damaged and, thus, cause many problems.

### BRIEF DESCRIPTION OF THE DRAWINGS

FIGS. 1a and 1b are schematic diagrams illustrating an example prior art process of void formation in an ILD layer.

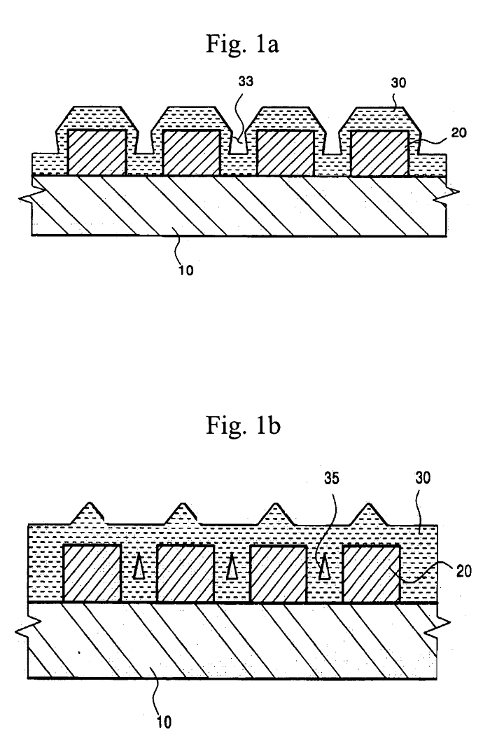

FIG. 2 is a flow chart of an example HDP process.

FIGS. 3a through 3c are schematic diagrams illustrating an example process of gap filling.

### DETAILED DESCRIPTION

A conventional HDP process includes depositing an ILD using SiH₄ or O₂ gas and simultaneously etching away some parts of the deposited ILD using physical collision by ionized argon to form a gap filling layer between interconnect lines or in trenches. The conventional HDP process can create an ILD having gap fill capability using SiH₄, O₂ gas, argon gas, and an RF plasma source by simultaneous performing etching of the ILD while the ILD is deposited. However, spacing between adjacent interconnect lines and/or the width of trenches become narrower and narrower, as the design rule in semiconductor technology increasingly reduces. Accordingly, the deposition speed becomes relatively fast at the side walls near the top corner of interconnect lines or trenches and the sputter-etched ILD material (SiO₂, SiOF) may be re-deposited to clog the upper parts of the gaps, thereby causing void formation.

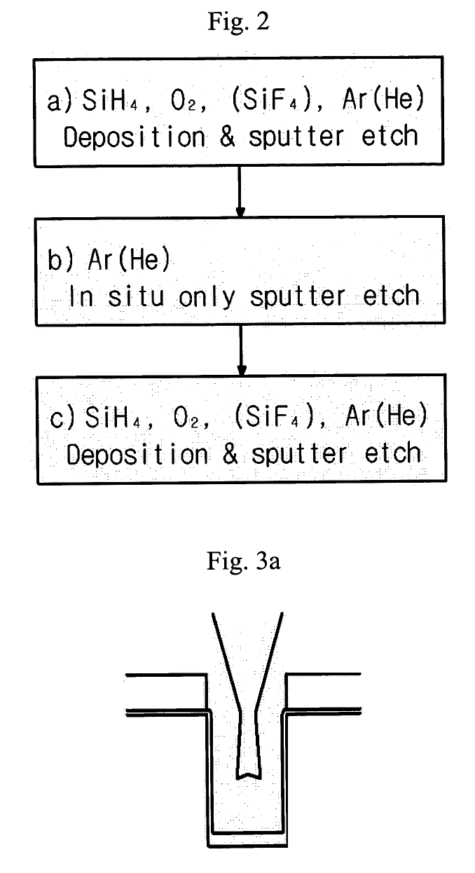

FIG. 2 is a flow chart of an example HDP process that avoids these problems. Unlike the prior, instead of performing sputter-etching and deposition while simultaneously controlling the gas for ILD deposition (e.g., SiH₄, O₂, and SiF₄) together with the gas for sputter-etching (e.g., Ar gas or He gas), the HDP process of FIG. 2 temporarily suspends the supply of the gas for ILD deposition into the chamber while sputter etching is performed. Therefore, the upper parts of the gaps between adjacent interconnect lines or trenches, which are narrowed during deposition, are broadened by the sputter etching. Then, the gas for ILD deposition is again directed into the chamber and the sputter etching and deposition are simultaneously performed to form a void free gap filling layer. Two working examples of the HDP process of FIG. 2 are described below.

### EXAMPLE 1

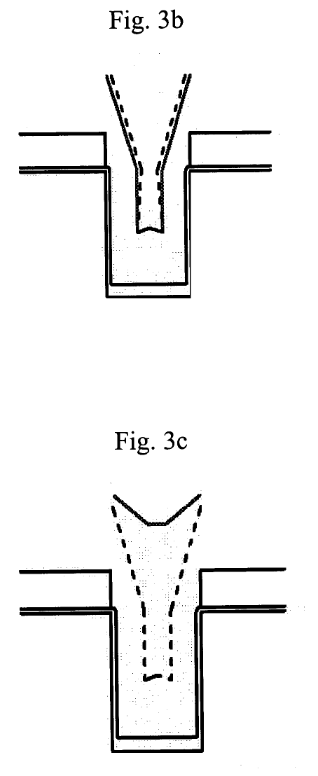

First, a substrate having at least one predetermined structure including a metal interconnect is moved into a chamber. SiH₄, O₂ and Ar gases are directed into the chamber, respectively. Deposition and sputter etching are then performed simultaneously to deposit a first ILD over the substrate. The deposition and sputter etching are preferably performed until the thickness of the first ILD reaches half of the desired thickness of the final ILD (see FIG. 3a). For example, if the desired thickness of the final HDP ILD is 6,000 Å, the thickness of the first formed ILD is about 3000 Å.

Next, the supply of SiH₄ gas into the chamber is suspended, and only O₂ and Ar gases are directed into the chamber. Therefore, only sputter etching is performed in the chamber to remove some parts of the first ILD. For example, sputter etching is performed until the thickness of the first ILD reaches about 2,000 Å (see FIG. 3b).

Next, the SiH₄ gas is again flowed into the chamber, and deposition and sputter etching are again performed simultaneously to form a second ILD (FIG. 3c).

Accordingly, the narrowed entrance of the gaps between adjacent interconnect lines are broadened by removing some parts of the first ILD by pausing deposition while continuing sputter etching. Then, deposition and sputter etching are performed simultaneously once more, thereby producing a void free ILD having excellent gap fill capability.

### EXAMPLE 2

A substrate having at least one predetermined structure including shallow trench isolation (hereinafter referred to as ^{˜}STI”) is moved into a chamber. SiH₄, O₂ and He gases are directed into the chamber, and deposition and sputter etching are then performed simultaneously to deposit a first ILD over the substrate. The deposition and sputter etching are preferably performed until the thickness of the first ILD reaches half of the desired thickness of the final ILD (see FIG. 3a). For example, if the desired thickness of the final HDP ILD is 6,000 Å, the thickness of the first formed ILD is about 3000 Å.

Next, the supply of SiH₄ gas into the chamber is suspended, and only O₂ and Ar gases are directed into the chamber. Therefore, only sputter etching is performed in the chamber to remove some parts of the first ILD. For example, sputter etching is performed until the thickness of the first ILD reaches about 2,000 Å (see FIG. 3b).

Next, the SiH₄ gas is again flowed into the chamber, and deposition and sputter etching are again performed simultaneously to form a second ILD (FIG. 3c).

Accordingly, the narrowed entrances of the trenches are broadened by removing some parts of the first ILD by pausing deposition while continuing only sputter etching. Then, deposition and sputter etching are simultaneously performed once more, thereby producing a void free ILD of excellent gap fill capability.

Therefore, by improving the HDP process so that void forming can be reduced or eliminated, the example methods disclosed herein can avoid topology defects such as oxide hole defects which may occur during the following CMP planarization process due to voids formed in the ILD and STI. The methods disclosed herein can also prevent reliability deterioration due to sinkage around the voids.

From the foregoing, persons of ordinary skill in the art will appreciate that the above disclosed methods form a void free ILD by enhancing gap fill capability through an improved HDP process. An example process for forming a gap filling layer using HDP, comprises: moving a substrate having at least one predetermined structure into a chamber; directing at least one gas for ILD deposition and at least one gas for etching into the chamber; depositing a first ILD over the substrate until the thickness of the first ILD reaches a predetermined thickness; suspending the supply of gas for ILD deposition into the chamber; removing some parts of the first ILD; directing again the gas for ILD deposition into the chamber; and depositing a second ILD on the first ILD.

Although certain example methods and apparatus have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method for forming a gap filling layer using high density plasma comprising:
directing at least one gas for ILD deposition and at least one gas for etching into a chamber containing a substrate having at least one predetermined structure;
depositing a first ILD over the substrate until a thickness of the first ILD reaches a predetermined thickness;
suspending supply of the gas for ILD deposition into the chamber;
removing at least one part of the first ILD;
re-starting the supply of the gas for ILD deposition into the chamber; and
depositing a second ILD on the first ILD.

2. A method as defined by claim 1, wherein the substrate having at least one predetermined structure comprises at least one metal layer on a top thereof.

3. A method as defined by claim 1, wherein the substrate having at least one predetermined structure comprises at least one open trench.

4. A method as defined by claim 1, wherein the gas for ILD deposition is selected from the group comprising SiH₄, O₂, and SIF₄.

5. A method as defined by claim 1, wherein the gas for etching is selected from the group comprising Ar, He, and O₂.

6. A method as defined by claim 1, wherein the first ILD is formed until its thickness reaches about one-half of a desired thickness of a final ILD.

7. A method as defined by claim 1, wherein edges of the first ILD are removed by sputter etching.
